(19) United States
(12) Patent Application Publication
(10) Pub. No.: US 2026/0078524 A1
(43) Pub. Date: Mar. 19, 2026

(54) VAPOR PHASE GROWTH APPARATUS

(71) Applicants: Kabushiki Kaisha Toshiba, Tokyo (JP); Toshiba Electronic Devices & Storage Corporation, Tokyo (JP)

(72) Inventors: Masaharu SHIMABAYASHI, Ibo Hyogo (JP); Tsutomu KIYOSAWA, Himeji Hyogo (JP)

(21) Appl. No.: 19/040,289

(22) Filed: Jan. 29, 2025

(30) Foreign Application Priority Data
Sep. 18, 2024 (JP) 2024-160730

(51) Int. Cl. C30B 25/12; C23C 16/458

(52) U.S. Cl. CPC C30B 25/12; C23C 16/4584; C23C 16/4585

(57) ABSTRACT

A vapor phase growth apparatus of an embodiment has a susceptor configured to allow a wafer to be mounted thereon, a drive unit configured to rotate the susceptor, and a wafer guide having a ring shape to surround an outer edge of the wafer and being attached to the susceptor. An upward facing surface of the wafer guide is located below a level which is located 0.65 mm above an upward facing surface of the wafer.

### CROSS-REFERENCE TO RELATED APPLICATION

This application is based upon and claims the benefit of priority from Japanese Patent Application No. 2024-160730, filed Sep. 18, 2024, the entire contents of which are incorporated herein by reference.

### FIELD

Embodiments described herein relate generally to a vapor phase growth apparatus.

### BACKGROUND

Vapor phase growth apparatus, in which the uniformity of the thickness of a film is improved by depositing a SiC film or the like on a front surface of a wafer while a susceptor having the wafer mounted thereon is rotated, are known. In such vapor phase growth apparatus, in order to curb a situation in which the wafer falls off from the susceptor, a wafer guide having an upper surface located above the front surface of the wafer and surrounding the susceptor may be provided. In this case, since the flow rate of a material gas supplied to an outer edge of the front surface of the wafer in a radial direction will decrease if the position of the upper surface of the wafer guide is excessively high, there is concern that the thickness of a film deposited in the outer edge of the wafer in the radial direction may become thin. Therefore, there is concern that the uniformity of the thickness of the film may deteriorate.

### BRIEF DESCRIPTION OF THE DRAWINGS

FIG. 1 is a cross-sectional view showing a vapor phase growth apparatus of an embodiment.

FIG. 2 is a first cross-sectional view showing a part of the vapor phase growth apparatus of the embodiment.

FIG. 3 is a second cross-sectional view showing a part of the vapor phase growth apparatus of the embodiment.

FIG. 4 is a cross-sectional view showing a flow of a material gas in a vapor phase growth apparatus of a comparative example.

FIG. 5 is the first cross-sectional view showing a flow of the material gas in the vapor phase growth apparatus of the embodiment.

FIG. 6 is a view showing a deposition rate in an outer edge of a wafer in a radial direction in the vapor phase growth apparatus of the embodiment.

FIG. 7 is a view showing a variation in deposition rate of a film deposited on a front surface of the wafer of the vapor phase growth apparatus of the embodiment.

FIG. 8 is the second cross-sectional view showing a flow of the material gas in the vapor phase growth apparatus of the embodiment.

FIG. 9 is a view showing a deposition rate in a wafer guide of the vapor phase growth apparatus of the embodiment.

### DETAILED DESCRIPTION

A vapor phase growth apparatus of an embodiment has a susceptor configured to allow a wafer to be mounted thereon, a drive unit configured to rotate the susceptor, and a wafer guide having a ring shape to surround an outer edge of the wafer and being attached to the susceptor. An upward facing surface of the wafer guide is located below a level which is located 0.65 mm above an upward facing surface of the wafer.

Hereinafter, the vapor phase growth apparatus according to embodiments will be described with reference to the drawings.

In each of the drawings, a Z axis direction is a vertical direction. The side which the arrow in the Z axis direction faces (positive Z side) is an upward side in the vertical direction. The side opposite to the side which the arrow in the Z axis direction faces (negative Z side) is a downward side in the vertical direction. In the following description, the upward side in the vertical direction will be simply referred to as “an upward side”, and the downward side in the vertical direction will be simply referred to as “a downward side”. In the following description, an upward facing surface of an outer surface of each portion constituting the vapor phase growth apparatus may be referred to as a front surface, and a downward facing surface thereof may be referred to as a rear surface.

The direction, shown in each drawing, in which a rotation axis J extends is parallel to the Z axis direction. The rotation axis J is a virtual axis. In the vapor phase growth apparatus of the present embodiment, the susceptor rotates about the rotation axis J. In the following description, a radial direction about the rotation axis J will be simply referred to as “a radial direction”, and a circumferential direction about the rotation axis J will be simply referred to as “a circumferential direction”. In each drawing, the circumferential direction is indicated by the arrow θ.

In this specification, the terms such as “orthogonal”, “parallel”, “same”, and “similar”, the values of lengths and angles, and the like specifying the shape of each part constituting the vapor phase growth apparatus and the degree of the relative disposition relationship between parts will not be bound by their strict meanings and will be interpreted to include the range to the extent that similar functions can be expected and the range of design tolerances. In addition, each of the drawings is schematic and conceptual. The dimensions of each part constituting the vapor phase growth apparatus, the dimensional ratios between the parts, and the like are not necessarily the same as those in reality. Moreover, even when the same part is expressed, the dimensions and the ratios may be expressed differently from each other in each of the drawings.

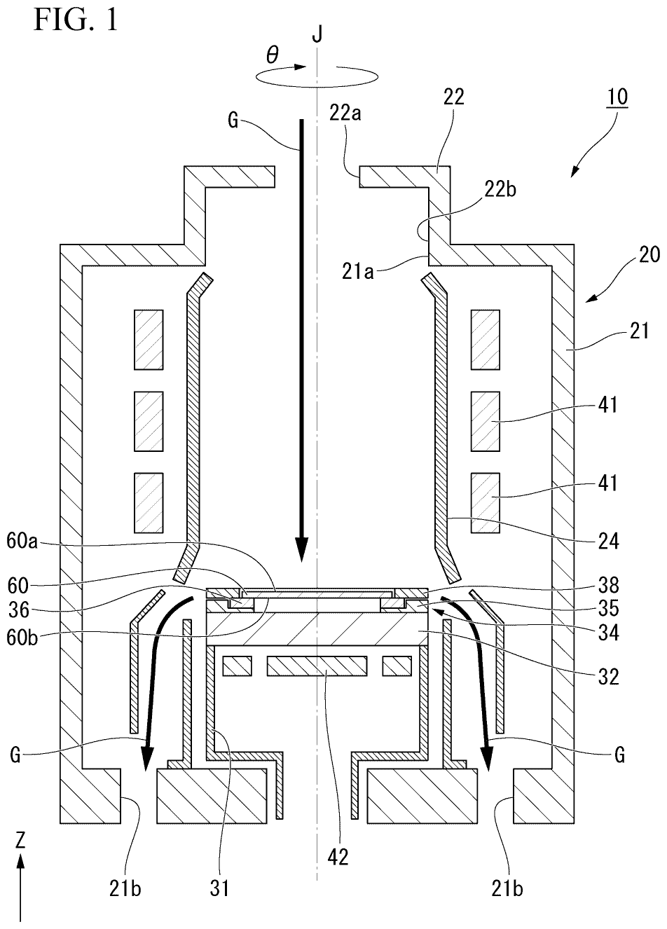

A vapor phase growth apparatus 10 of the present embodiment shown in FIG. 1 is a deposition apparatus for depositing an epitaxial film on a front surface 60a, that is, an upward facing surface of a wafer 60 by a chemical vapor deposition (CVD) method. In the present embodiment, a silicon carbide (SiC) film is deposited on the front surface 60a of the wafer 60. The film deposited on the front surface 60a of the wafer 60 may be a film constituted of a different material such as Si. The vapor phase growth apparatus 10 includes a chamber 20, a supply tube 24, a drive unit 31, a susceptor holding portion 32, a susceptor 34, a wafer guide 38, first heating portions 41, and a second heating portion 42.

The chamber 20 internally accommodates the supply tube 24, the drive unit 31, the susceptor holding portion 32, the susceptor 34, the wafer guide 38, the first heating portions 41, and the second heating portion 42. The chamber 20 has a main body portion 21 and a supply portion 22. In the present embodiment, the chamber 20 is made of metal.

The main body portion 21 internally accommodates the supply tube 24, the drive unit 31, the susceptor holding portion 32, the susceptor 34, the wafer guide 38, the first heating portions 41, and the second heating portion 42. The main body portion 21 has a tubular shape extending in the vertical direction. The main body portion 21 is provided with a main body portion opening 21a opening to the upward side. The main body portion 21 is provided with a discharge port 21b opening to the downward side. An excess material gas G inside the chamber 20 is discharged to the outside of the vapor phase growth apparatus 10 through the discharge port 21b.

The supply portion 22 has a tubular shape protruding to the upward side from the main body portion 21. The supply portion 22 is provided with a supply port 22a opening to the upward side. The supply portion 22 is provided with a supply portion opening 22b opening to the downward side. The inside of the supply portion 22 and the inside of the main body portion 21 are connected to each other via the supply portion opening 22b and the main body portion opening 21a. The material gas G supplied to the inside of the supply portion 22 through the supply port 22a is supplied to the inside of the main body portion 21 via the supply portion opening 22b and the main body portion opening 21a.

The supply tube 24 is accommodated inside the main body portion 21. The supply tube 24 has a tubular shape extending in the vertical direction. The supply tube 24 opens to both the upward side and the downward side. At the time of deposition, the material gas G flows toward the downward side inside the supply tube 24. At the time of deposition, the material gas G flowing toward the downward side inside the supply tube 24 is supplied to the front surface 60a of the wafer 60. The excess material gas G inside the supply tube 24 is discharged to the outside of the vapor phase growth apparatus 10 via the opening of the supply tube 24 on the downward side and the discharge port 21b. In the present embodiment, the supply tube 24 is made of graphite. A coating layer formed of materials such as SiC and tantalum carbide (TaC) may be provided on an inner surface of the supply tube 24.

In the present embodiment, the material gas G contains raw material gas, impurity gas, carrier gas, and hydrogen chloride (HCl) gas. The raw material gas contains silane (SiH₄) and propane (C₃H₈). The flow amount of the raw material gas is preferably in a range of several tens of [sccm] to several hundreds of [sccm]. The impurity gas contains nitrogen and trimethylaluminum (TMA). The flow amount of the impurity gas is preferably in a range of several [sccm] to several hundreds of [sccm]. The carrier gas is either argon gas or hydrogen gas. More specifically, the carrier gas used when the wafer 60 is carried into the vapor phase growth apparatus 10 and mounted on the susceptor 34 and when the wafer 60 after deposition is taken out from the susceptor 34 and carried out to the outside of the vapor phase growth apparatus 10 is argon gas. In addition, the carrier gas at the time of deposition is hydrogen gas. The flow amount of the carrier gas is preferably in a range of 100 [slm] to 200 [slm]. The flow amount of hydrogen chloride gas is preferably in a range of several tens of [sccm] to several [slm]. The flow amount and the like of each of the raw material gas, the impurity gas, the carrier gas, and the hydrogen chloride gas are adjusted by a gas adjustment portion (not shown).

The first heating portions 41 have a ring shape surrounding the supply tube 24. The first heating portions 41 are disposed between the main body portion 21 and the supply tube 24. In the present embodiment, the vapor phase growth apparatus 10 includes three first heating portions 41. The first heating portions 41 are disposed with a gap therebetween in the vertical direction. Each of the first heating portions 41 heats the material gas G passing through the inside of the supply tube 24. Accordingly, the temperature of the material gas G when it arrives at the wafer 60 can be increased, and therefore the deposition rate of a SiC film can be increased. In addition, each of silane and propane contained in the material gas G is subjected to pyrolysis into silylene (SiH2) and methane (CH4). The number of first heating portions 41 provided in the vapor phase growth apparatus 10 may be two or less or may be four or more.

The second heating portion 42 is disposed inside the drive unit 31. The second heating portion 42 is disposed on the downward side of the susceptor holding portion 32. At the time of deposition, the second heating portion 42 heats each of the susceptor holding portion 32, the susceptor 34, and the wafer 60. At the time of deposition, the second heating portion 42 heats the wafer 60 to a temperature of 1,500° C. to 1,650°C. If the material gas G is supplied to the front surface 60a of the wafer 60 which has been heated to such a temperature, the SiC film is deposited on the front surface 60a of the wafer 60.

The drive unit 31 includes a drive device such as a motor (not shown), for example. The drive unit 31 is rotated around the rotation axis J by the drive device. The drive unit 31 is supported by a bottom portion of the main body portion 21 such that it can rotate around the rotation axis J. The drive unit 31 is disposed on the downward side of the susceptor holding portion 32. The drive unit 31 rotates each of the susceptor holding portion 32, the susceptor 34, the wafer guide 38, and the wafer 60 around the rotation axis J. Accordingly, in the vapor phase growth apparatus 10 of the present embodiment, at the time of deposition of depositing the SiC film on the front surface 60a of the wafer 60, the wafer 60 can be rotated around the rotation axis J by the drive unit 31. For this reason, a variation in supply amount of the material gas G on the front surface 60a of the wafer 60 can be reduced. Therefore, the uniformity of the thickness of the film deposited on the front surface 60a of the wafer 60 can be improved.

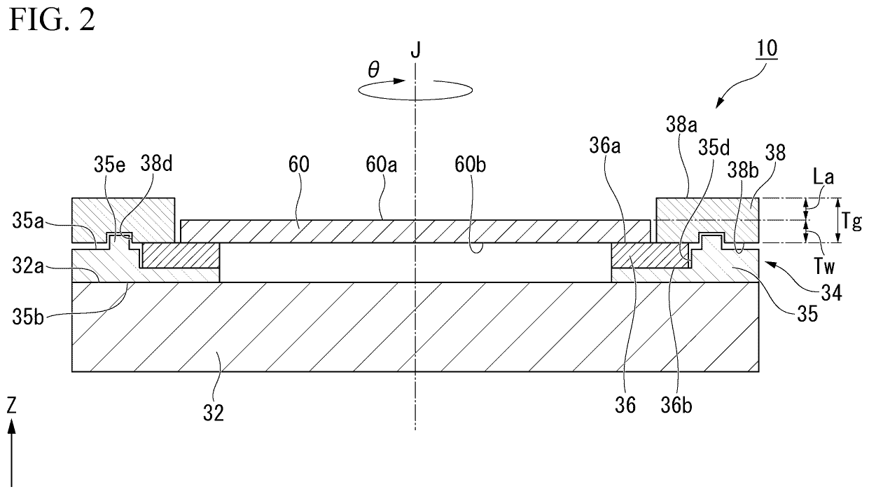

The susceptor holding portion 32 has a plate shape extending in a direction orthogonal to the vertical direction. In the present embodiment, the susceptor holding portion 32 substantially has a disk shape about the rotation axis J. When viewed in the vertical direction, the susceptor holding portion 32 may have a different shape such as an elliptical shape. As shown in FIG. 2, the susceptor 34 is fixed to a front surface 32a of the susceptor holding portion 32. Accordingly, the susceptor holding portion 32 holds the susceptor 34. In the present embodiment, the susceptor holding portion 32 is made of graphite. The outer surface of the susceptor holding portion 32 may be provided with a coating layer formed of a material such as SiC and TaC.

The wafer 60 is mounted on the susceptor 34. The susceptor 34 supports the wafer 60 from the downward side. In the present embodiment, the susceptor 34 has substantially a toric shape about the rotation axis J. As described above, the susceptor 34 is held in the susceptor holding portion 32. The susceptor 34 has a holding portion 35 and a cover base 36.

The holding portion 35 has substantially a toric shape about the rotation axis J. The holding portion 35 is disposed on the upward side of the susceptor holding portion 32. A rear surface 35b of the holding portion 35 is fixed to the front surface 32a of the susceptor holding portion 32. The outer diameter of the holding portion 35 and the outer diameter of the susceptor holding portion 32 are substantially the same dimensions. The holding portion 35 is provided with a holding groove portion 35d and a projecting portion 35e. The holding groove portion 35d is recessed to the downward side from a front surface 35a of the holding portion 35. The holding groove portion 35d opens to the inward side in the radial direction. The projecting portion 35e is a projection protruding to the upward side from the front surface 35a of the holding portion. The projecting portion 35e has substantially a toric shape about the rotation axis J. In the present embodiment, the holding portion 35 is made of graphite. The outer surface of the holding portion 35 may be provided with a coating layer formed of a material such as SiC and TaC.

The cover base 36 has substantially a toric shape about the rotation axis J. The cover base 36 is disposed inside the holding groove portion 35d. A rear surface 36b of the cover base 36 is fixed to the upward facing surface of the holding groove portion 35d. In the present embodiment, a front surface 36a of the cover base 36 is located above the front surface 35a of the holding portion 35. In the vertical direction, the front surface 36a of the cover base 36 may be at the same level as the front surface 35a of the holding portion 35. The cover base 36 supports the wafer guide 38 from the downward side. At the time of deposition, the wafer 60 is mounted on the front surface 36a of the cover base 36. Accordingly, the wafer 60 is mounted on the susceptor 34. In the present embodiment, the cover base 36 is made of graphite. The outer surface of the cover base 36 may be provided with a coating layer formed of a material such as SiC and TaC. In the present embodiment, the holding portion 35 and the cover base 36 are members different from each other. The holding portion 35 and the cover base 36 may be integrally molded.

The wafer guide 38 has a ring shape surrounding the rotation axis J. In the present embodiment, the wafer guide 38 has substantially a toric shape about the rotation axis J. The wafer guide 38 is disposed on the upward side from the cover base 36. The inner diameter of the wafer guide 38 is larger than the inner diameter of the cover base 36. The wafer guide 38 is provided with a recessed portion 38d. The recessed portion 38d is a depression depressed to the upward side from a rear surface 38b of the wafer guide 38. When viewed from the downward side, the recessed portion 38d has substantially a toric shape about the rotation axis J. The projecting portion 35e is accommodated inside the recessed portion 38d. The projecting portion 35e is engaged with the recessed portion 38d. Accordingly, the wafer guide 38 can rotate around the rotation axis J together with the susceptor 34. The outer diameter of the wafer guide 38 has substantially the same dimension as the outer diameter of the holding portion 35. At the time of deposition, the wafer guide 38 surrounds the outer edge of the wafer 60 mounted in the cover base 36 from the outward side in the radial direction. The inner diameter of the wafer guide 38 is slightly larger than the outer diameter of the wafer 60. At the time of deposition, an inward side surface of the wafer guide 38 radially comes into contact with the wafer 60 rotating around the rotation axis J. Accordingly, at the time of deposition, a situation in which the wafer 60 falls off from the susceptor 34 can be curbed. A thickness Tg of the wafer guide 38 shown in FIG. 2 is a dimension of the wafer guide 38 in the vertical direction. In the present embodiment, the wafer guide 38 is made of poly-SiC. The wafer guide 38 may be made of graphite. In this case, the front surface of the wafer guide 38 may be provided with a coating layer constituted using SiC.

The wafer 60 substantially has a disk shape extending in a direction orthogonal to the vertical direction. In the present embodiment, the wafer 60 is constituted using SiC. More specifically, in the present embodiment, the wafer 60 is constituted using single crystal SiC. The wafer 60 may be constituted using polycrystal SiC. The material constituting the wafer 60 may be a different material such as Si. At the time of deposition, the wafer 60 is mounted in a part on the front surface 36a of the cover base 36 on the inward side in the radial direction. A rear surface 60b of the wafer 60 comes into contact with the front surface 36a of the cover base 36 in the vertical direction. In the present embodiment, a thickness Tw of the wafer 60 is 0.35 mm. The thickness Tw of the wafer 60 is a dimension of the wafer 60 in the vertical direction. The thickness Tw of the wafer 60 may be thinner than 0.35 mm or may be thicker than 0.35 mm. In the present embodiment, the thickness of the SiC film deposited on the front surface 60a of the wafer 60 is 0.5 to 100 μm.

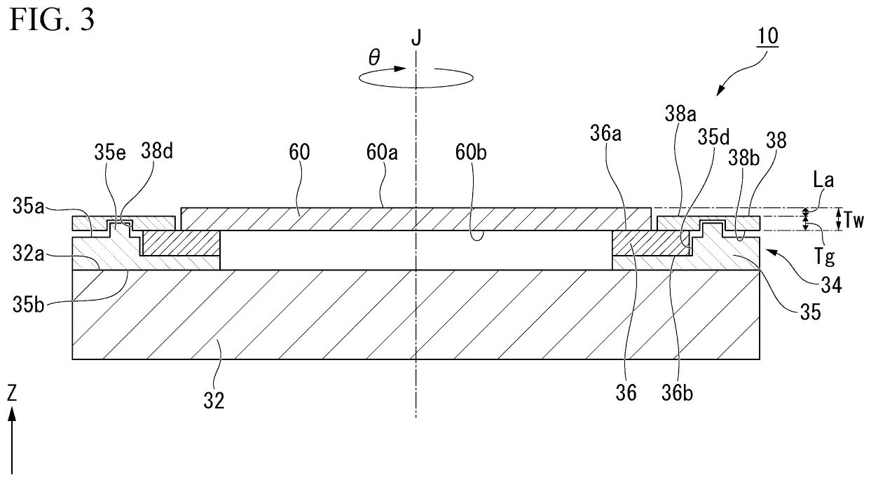

A protrusion height La shown in FIG. 2 is a distance between a front surface 38a of the wafer guide 38 and the front surface 60a of the wafer 60 in the vertical direction. As described above, in the present embodiment, each of the wafer guide 38 and the wafer 60 is supported by the cover base 36 from the downward side. Therefore, in the present embodiment, the protrusion height La is a difference between the thickness Tg of the wafer guide 38 and the thickness Tw of the wafer 60. In the present embodiment, as shown in FIG. 2, when the thickness Tg of the wafer guide 38 is thicker than the thickness Tw of the wafer 60, that is, when the front surface 38a of the wafer guide 38 is located above the front surface 60a of the wafer 60, the protrusion height La has a positive value. Although illustration is omitted, when the thickness Tg of the wafer guide 38 and the thickness Tw of the wafer 60 are the same thickness, the protrusion height La is zero. In the present embodiment, as shown in FIG. 3, when the thickness Tg of the wafer guide 38 is thinner than the thickness Tw of the wafer 60, that is, when the front surface 38a of the wafer guide 38 is located below the front surface 60a of the wafer 60, the protrusion height La has a negative value. In the present embodiment, the protrusion height La is 0.65 mm or smaller. That is, in the present embodiment, the front surface 38a of the wafer guide 38, that is, the upward facing surface is located below the level which is located 0.65 mm above the front surface 60a of the wafer 60, that is, the upward facing surface. In the present embodiment, the thickness Tg of the wafer guide 38 is thinner than 1.00 mm.

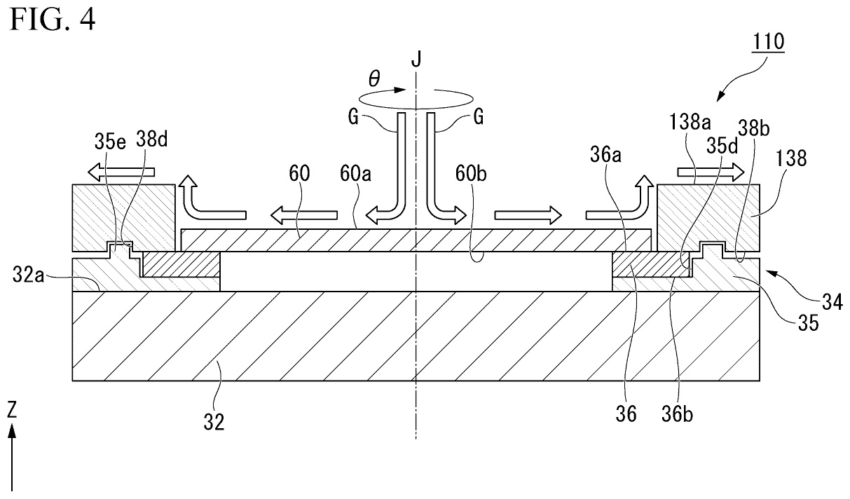

The thickness Tg of a wafer guide 138 included in a vapor phase growth apparatus 110 of a comparative example shown in FIG. 4 is 1.85 mm, for example. Therefore, in the vapor phase growth apparatus 110 of the comparative example, the protrusion height La is 1.50 mm, for example. In the vapor phase growth apparatus 110 of the comparative example, a front surface 138a of the wafer guide 138 is located above the level which is located 0.65 mm above the front surface 60a of the wafer 60. As described above, at the time of deposition of depositing the SiC film on the front surface 60a of the wafer 60, the material gas G flowing toward the downward side inside the supply tube 24 shown in FIG. 1 is supplied to the front surface 60a of the wafer 60. In addition, as described above, at the time of deposition, if the material gas G is supplied to the front surface 60a of the wafer 60 heated by the second heating portion 42, the SiC film is deposited on the front surface 60a of the wafer 60.

As shown in FIG. 4, at the time of deposition, the material gas G supplied to the front surface 60a of the wafer 60 flows toward the outward side in the radial direction along the front surface 60a of the wafer 60. Accordingly, the material gas G can be supplied to the entire front surface 60a of the wafer 60. However, when the protrusion height La is excessively large as in the vapor phase growth apparatus 110 of the comparative example, a flow of the material gas G flowing toward the outward side of the wafer 60 in the radial direction from the outer edge of the wafer 60 in the radial direction is hindered noticeably by the wafer guide 138. Accordingly, since the flow rate of the material gas G in the outer edge of the wafer 60 in the radial direction decreases significantly, a deposition rate GR1 in the outer edge on the front surface 60a of the wafer 60 in the radial direction decreases significantly. Therefore, since the thickness of the film deposited in the outer edge of the wafer 60 in the radial direction becomes excessively thinner than the thickness of the film deposited in a central portion of the wafer 60 in the radial direction, it is difficult to improve the uniformity of the thickness of the film deposited on the front surface 60a of the wafer 60.

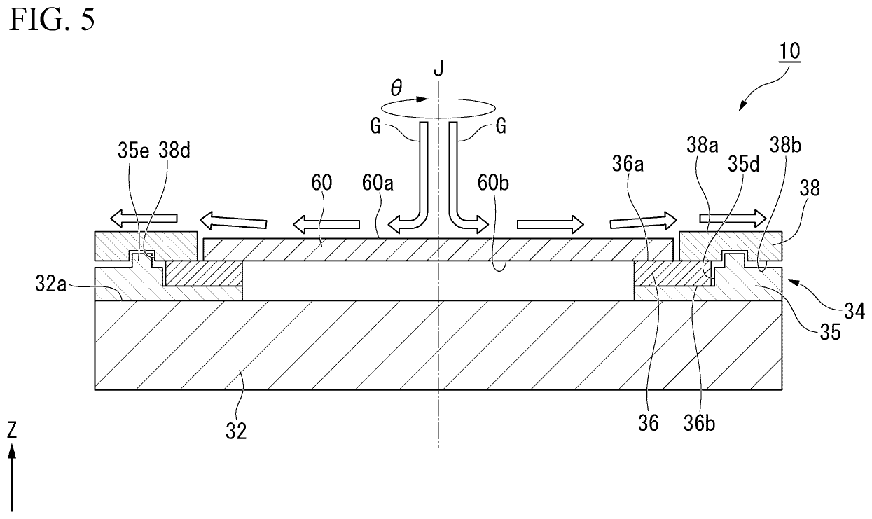

In contrast, as described above, in the vapor phase growth apparatus 10 of the present embodiment, the protrusion height La is smaller than 0.65 mm. For this reason, excessive increase in protrusion height La can be curbed. Therefore, as shown in FIG. 5, in the present embodiment, a hindrance to a flow of the material gas G flowing toward the outward side of the wafer 60 in the radial direction from the outer edge of the wafer 60 in the radial direction by the wafer guide 38 can be curbed. Accordingly, since decrease in flow rate of the material gas G in the outer edge of the wafer 60 in the radial direction can be curbed, decrease in deposition rate GR1 in the outer edge on the front surface 60a of the wafer 60 in the radial direction can be curbed. Therefore, since a situation in which the thickness of the film deposited in the outer edge of the wafer 60 in the radial direction becomes excessively thinner than the thickness of the film deposited in the central portion of the wafer 60 in the radial direction can be curbed, the uniformity of the thickness of the film deposited on the front surface 60a of the wafer 60 can be improved.

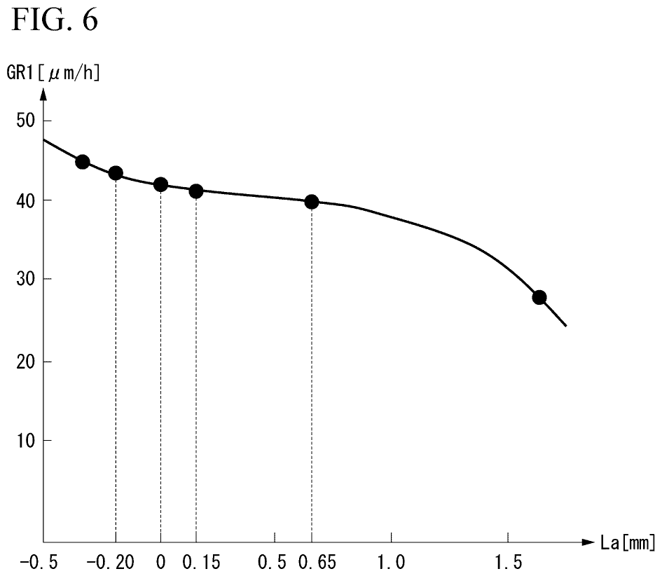

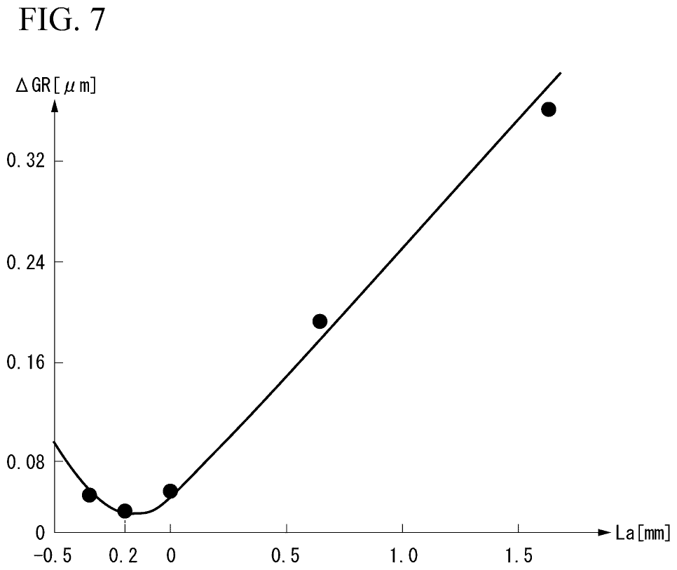

FIG. 6 is a view showing the deposition rate GR1 in the outer edge of the wafer 60 in the radial direction in the vapor phase growth apparatus 10 of the present embodiment. The horizontal axis in FIG. 6 is the protrusion height La. The vertical axis in FIG. 6 is the deposition rate GR1 in the outer edge on the front surface 60a of the wafer 60 in the radial direction. In the present embodiment, a deposition rate GR2 in the central portion on the front surface 60a of the wafer 60 in the radial direction is approximately 44 μm/h. FIG. 7 is a view showing a variation in deposition rate of a film deposited on the front surface 60a of the wafer 60 in the vapor phase growth apparatus 10 of the present embodiment. In the following description, the variation in deposition rate of the film deposited on the front surface 60a may be referred to as a variation ΔGR in deposition rate. In the present embodiment, when the maximum rate of the deposition rate within the front surface 60a is GRmax, the minimum rate of the deposition rate within the front surface 60a is GRmin, and the average rate of the deposition rate within the front surface 60a is GRave, the variation ΔGR in deposition rate is (GRmax−GRmin)/(2×GRave). The horizontal axis in FIG. 7 is the protrusion height La. The vertical axis in FIG. 7 is the variation ΔGR in deposition rate.

As shown in FIG. 6, the deposition rate GR1 decreases as the protrusion height La increases. This is because, as described above, as the protrusion height La increases, the flow rate of the material gas G in the outer edge of the wafer 60 in the radial direction decreases. In a range in which the protrusion height La is larger than 0.65 mm, the deposition rate GR1 decreases significantly as the protrusion height La increases. This is because the flow rate of the material gas G in the outer edge of the wafer 60 in the radial direction decreases remarkably since the protrusion height La becomes excessively large. For this reason, in the range in which the protrusion height La is larger than 0.65 mm, the difference between the deposition rate GR1 in the outer edge on the front surface 60a of the wafer 60 in the radial direction and the deposition rate GR2 in the central portion on the front surface 60a of the wafer 60 in the radial direction becomes large. Therefore, as shown in FIG. 7, when the protrusion height La is larger than 0.65 mm, that is, when the front surface 38a of the wafer guide 38 is located above the level which is located 0.65 mm above the front surface 60a of the wafer 60, the variation ΔGR in deposition rate increases. Accordingly, the uniformity of the thickness of the film deposited on the front surface 60a of the wafer 60 deteriorates.

In contrast, as shown in FIG. 6, in a range in which the protrusion height La is smaller than 0.65 mm, the deposition rate GR1 decreases gently as the protrusion height La increases. This is because decrease in flow rate of the material gas G in the outer edge of the wafer 60 in the radial direction can be curbed since excessive increase in protrusion height La can be curbed. For this reason, in the range in which the protrusion height La is smaller than 0.65 mm, the difference between the deposition rate GR1 in the outer edge on the front surface 60a of the wafer 60 in the radial direction and the deposition rate GR2 in the central portion on the front surface 60a of the wafer 60 in the radial direction can be reduced. Therefore, as shown in FIG. 7, when the protrusion height La is smaller than 0.65 mm, that is, when the front surface 38a of the wafer guide 38 is located below the level which is located 0.65 mm above the front surface 60a of the wafer 60, the variation ΔGR in deposition rate can be reduced. Accordingly, the uniformity of the thickness of the film deposited on the front surface 60a of the wafer 60 can be improved.

In the present embodiment, it is preferable that the front surface 38a of the wafer guide 38, that is, the upward facing surface be located below the level which is located 0.15 mm above the front surface 60a of the wafer 60, that is, the upward facing surface. Namely, it is preferable that the protrusion height La be smaller than 0.15 mm. Accordingly, as shown in FIG. 6, decrease in deposition rate GR1 in the outer edge on the front surface 60a of the wafer 60 in the radial direction can be more favorably curbed. Therefore, the difference between the deposition rate GR1 in the outer edge on the front surface 60a of the wafer 60 in the radial direction and the deposition rate GR2 in the central portion on the front surface 60a of the wafer 60 in the radial direction can be more favorably reduced. Therefore, as shown in FIG. 7, since the variation ΔGR in deposition rate can be more favorably reduced, the uniformity of the thickness of the film can be more favorably improved.

In the present embodiment, it is preferable that the front surface 38a of the wafer guide 38, that is, the upward facing surface be located above the level which is located 0.20 mm below the front surface 60a of the wafer 60, that is, the upward facing surface. Namely, it is preferable that the protrusion height La be larger than −0.20 mm. As shown in FIG. 6, the deposition rate GR1 increases as the protrusion height La decreases. In the present embodiment, if the protrusion height La becomes smaller than −0.20 mm, the deposition rate GR1 in the outer edge on the front surface 60a of the wafer 60 in the radial direction becomes higher than the deposition rate GR2 in the central portion on the front surface 60a of the wafer 60 in the radial direction. For this reason, as shown in FIG. 7, the variation ΔGR in deposition rate increases as the protrusion height La becomes smaller than −0.20 mm. Accordingly, the uniformity of the thickness of the film deposited on the front surface 60a of the wafer 60 deteriorates. In contrast, a situation in which the deposition rate GR1 in the outer edge on the front surface 60a of the wafer 60 in the radial direction becomes higher than the deposition rate GR2 in the central portion on the front surface 60a of the wafer 60 in the radial direction can be curbed by causing the protrusion height La to be larger than −0.20 mm. Therefore, since the variation ΔGR in deposition rate can be reduced, the uniformity of the thickness of the film can be improved.

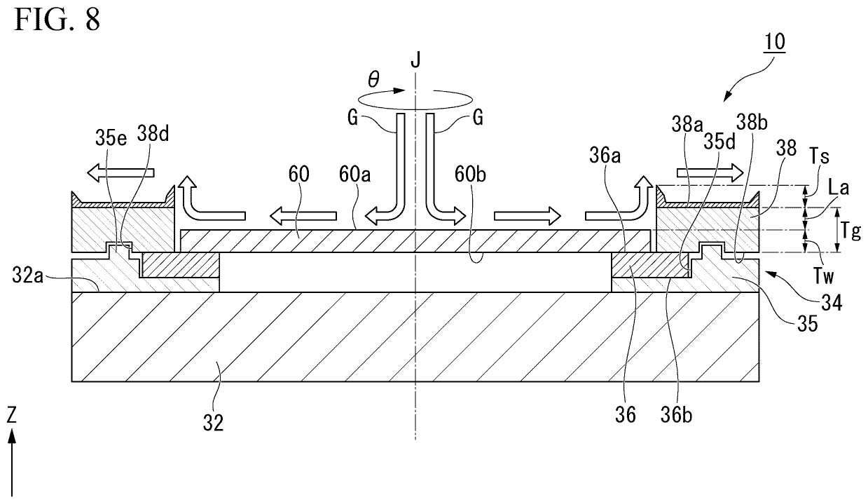

As shown in FIG. 5, in the present embodiment, at the time of deposition, the material gas G flowing toward the outward side of the wafer 60 in the radial direction from the outer edge of the wafer 60 in the radial direction flows toward the outward side in the radial direction along the front surface 38a of the wafer guide 38. For this reason, as shown in FIG. 8, at the time of deposition, the SiC film is deposited on the front surface 38a of the wafer guide 38. If the film thickness of the SiC film deposited on the front surface 38a of the wafer guide 38 becomes thick, a flow of the material gas G flowing toward the outward side of the wafer 60 in the radial direction from the outer edge of the wafer 60 in the radial direction is hindered due to such a SiC film. Accordingly, since the flow rate of the material gas G in the outer edge of the wafer 60 in the radial direction decreases significantly, the deposition rate GR1 in the outer edge on the front surface 60a of the wafer 60 in the radial direction decreases significantly. Particularly, if a film thickness Ts of the SiC film in an inner edge of the wafer guide 38 in the radial direction becomes thick, a flow of the material gas G flowing toward the outward side of the wafer 60 in the radial direction from the outer edge of the wafer 60 in the radial direction is hindered noticeably. For this reason, in the present embodiment, if the film thickness Ts of the SiC film in the inner edge of the wafer guide 38 in the radial direction reaches a predetermined thickness, replacement work of the wafer guide 38 is performed. Accordingly, deterioration in uniformity of the film deposited on the front surface 60a of the wafer 60 can be curbed.

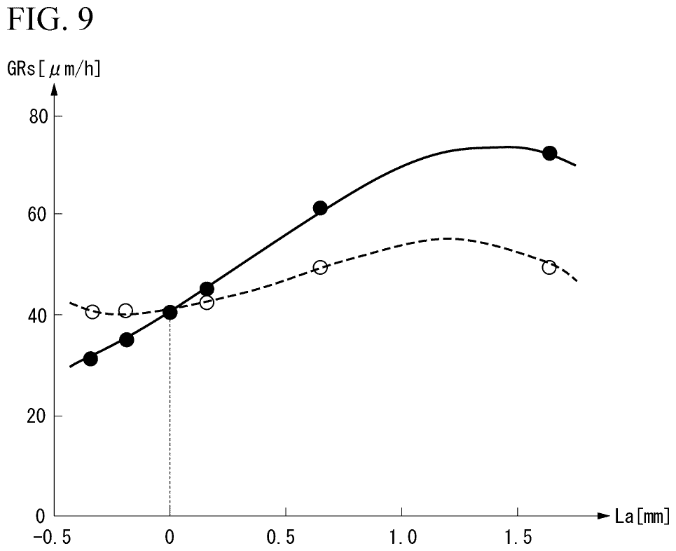

FIG. 9 is a view showing a deposition rate GRs in the wafer guide 38 of the vapor phase growth apparatus 10 of the present embodiment. The horizontal axis in FIG. 9 is the protrusion height La. The vertical axis in FIG. 9 is a deposition rate GRs of the SiC film deposited on the front surface 38a of the wafer guide 38. The deposition rate GRs in the inner edge of the wafer guide 38 in the radial direction is indicated by a solid line. The deposition rate GRs in the central portion of the wafer guide 38 in the radial direction is indicated by a dashed line.

As shown in FIG. 9, the deposition rate GRs in the central portion of the wafer guide 38 in the radial direction indicated by the dashed line becomes stable in a range of 40 [μm/h] to 50 [μm/h] regardless of the protrusion height La. In contrast, the deposition rate GRs in the inner edge of the wafer guide 38 in the radial direction indicated by a solid line decreases as the protrusion height La becomes small. This is because it is conceivable that the flow rate of the material gas G flowing in the inner edge of the wafer guide 38 in the radial direction decreases since the amount of the material gas G staying in the outer edge of the wafer 60 in the radial direction decreases as the protrusion height La becomes small. In the present embodiment, when the protrusion height La is smaller than 0.00 mm, that is, when the front surface 38a of the wafer guide 38 is located below the front surface 60a of the wafer 60, the deposition rate GRs in the inner edge of the wafer guide 38 in the radial direction becomes lower than the deposition rate GRs in the central portion of the wafer guide 38 in the radial direction. Accordingly, when one wafer guide 38 is continuously used while the SiC film is deposited on a plurality of wafers 60, it is possible to increase the number of wafers 60 which can be deposited until the film thickness Ts of the SiC film in the inner edge of the wafer guide 38 in the radial direction reaches a predetermined thickness. Namely, the number of wafers 60 which can be deposited using one wafer guide 38 can be increased. Therefore, the replacement frequency of the wafer guide 38 can be reduced.

According to the present embodiment, the vapor phase growth apparatus 10 includes the susceptor 34 configured to allow the wafer 60 to be mounted thereon, the drive unit 31 configured to rotate the susceptor 34, and the wafer guide 38 having a ring shape to surround the outer edge of the wafer 60 and being attached to the susceptor 34. The front surface 38a of the wafer guide 38, that is, the upward facing surface is located below the level which is located 0.65 mm above the front surface 60a of the wafer 60, that is, the upward facing surface. As described above, if the protrusion height La, which is a distance between the front surface 38a of the wafer guide 38 and the front surface 60a of the wafer 60 in the vertical direction, becomes excessively large, a flow of the material gas G flowing toward the outward side of the wafer 60 in the radial direction from the outer edge of the wafer 60 in the radial direction is hindered noticeably by the wafer guide 38. Accordingly, as described above, since the deposition rate GR1 in the outer edge on the front surface 60a of the wafer 60 in the radial direction decreases significantly, the thickness of the film deposited in the outer edge of the wafer 60 in the radial direction becomes thin. Therefore, it is difficult to improve the uniformity of the thickness of the film deposited on the front surface 60a of the wafer 60. In contrast, in the present embodiment, since the protrusion height La is 0.65 mm or smaller, excessive increase in protrusion height La can be curbed. Accordingly, as described above, the difference between the deposition rate GR1 in the outer edge on the front surface 60a of the wafer 60 in the radial direction and the deposition rate GR2 in the central portion on the front surface 60a of the wafer 60 in the radial direction can be reduced. Therefore, the uniformity of the thickness of the film deposited on the front surface 60a of the wafer 60 can be improved.

According to the present embodiment, the front surface 38a of the wafer guide 38, that is, the upward facing surface is located below the level which is located 0.15 mm above the front surface 60a of the wafer 60, that is, the upward facing surface. Accordingly, as described above, decrease in deposition rate GR1 in the outer edge on the front surface 60a of the wafer 60 in the radial direction can be more favorably curbed. For this reason, the difference between the deposition rate GR1 in the outer edge on the front surface 60a of the wafer 60 in the radial direction and the deposition rate GR2 in the central portion on the front surface 60a of the wafer 60 in the radial direction can be more favorably reduced. Therefore, the uniformity of the thickness of the film deposited on the front surface 60a of the wafer 60 can be more favorably improved.

According to the present embodiment, the front surface 38a of the wafer guide 38, that is, the upward facing surface is located below the front surface 60a of the wafer 60, that is, the upward facing surface. Accordingly, as described above, the deposition rate GRs in the inner edge of the wafer guide 38 in the radial direction can be made lower than the deposition rate GRs in the central portion of the wafer guide 38 in the radial direction. For this reason, as described above, when one wafer guide 38 is continuously used while the SiC film is deposited on a plurality of wafers 60, it is possible to increase the number of wafers 60 which can be deposited until the film thickness Ts of the SiC film in the inner edge of the wafer guide 38 in the radial direction reaches a predetermined thickness. Accordingly, the number of wafers 60 which can be deposited using one wafer guide 38 can be increased. Therefore, the replacement frequency of the wafer guide 38 can be reduced, and thus the workability of work of depositing the SiC film on the wafer 60 can be enhanced.

In addition, in the present embodiment, since the protrusion height La can be made 0.00 mm or smaller, excessive increase in protrusion height La can be more favorably curbed. Accordingly, as shown in FIG. 6, decrease in deposition rate GR1 in the outer edge on the front surface 60a of the wafer 60 in the radial direction can be more favorably curbed. Therefore, the uniformity of the thickness of the film deposited on the front surface 60a of the wafer 60 can be more favorably improved.

According to the present embodiment, the front surface 38a of the wafer guide 38, that is, the upward facing surface is located above the level which is located 0.20 mm below the front surface 60a of the wafer 60, that is, the upward facing surface. Accordingly, as described above, a situation in which the deposition rate GR1 in the outer edge on the front surface 60a of the wafer 60 in the radial direction becomes higher than the deposition rate GR2 in the central portion on the front surface 60a of the wafer 60 in the radial direction can be curbed. Therefore, the uniformity of the thickness of the film deposited on the front surface 60a of the wafer 60 can be improved.

According to the vapor phase growth apparatus of the embodiment described above, the upward facing surface of the wafer guide is located below the level which is located 0.65 mm above the upward facing surface of the wafer. Accordingly, the uniformity of the thickness of the film deposited on the front surface of the wafer can be improved.

While certain embodiments have been described, these embodiments have been presented by way of example only and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A vapor phase growth apparatus comprising:
a susceptor configured to allow a wafer to be mounted thereon;
a drive unit configured to rotate the susceptor; and
a wafer guide having a ring shape to surround an outer edge of the wafer and being attached to the susceptor,
wherein an upward facing surface of the wafer guide is located below a level which is located 0.65 mm above an upward facing surface of the wafer.

2. The vapor phase growth apparatus according to claim 1,
wherein an upward facing surface of the wafer guide is located below a level which is located 0.15 mm above an upward facing surface of the wafer.

3. The vapor phase growth apparatus according to claim 1,
wherein an upward facing surface of the wafer guide is located below an upward facing surface of the wafer.

4. The vapor phase growth apparatus according to claim 1,
wherein an upward facing surface of the wafer guide is located above a level which is located 0.20 mm below an upward facing surface of the wafer.
